(19) United States
(12) Patent Application Publication
(10) Pub. No.: US 2023/0087598 A1
(43) Pub. Date: Mar. 23, 2023

(54) STACKABLE POWER STORAGE SYSTEM

(71) Applicant: DISANKO INC., Longueuil (CA)

(72) Inventors: Jonathan LAMER, Chambly (CA); Mario LEBOEUF, Tuen Mun (HK); Alvaro Omar Macias Fernandez, Trois-Rivières (CA)

(21) Appl. No.: 17/951,398

(22) Filed: Sep. 23, 2022

Related U.S. Application Data
(60) Provisional application No. 63/247,403, filed on Sep. 23, 2021.

(51) Int. Cl. H02J 7/00; H05K 7/02; H01M 50/213; H01M 50/258; H01M 50/514; H01M 50/264

(52) U.S. Cl. CPC H02J 7/0045; H02J 7/0063; H05K 7/023; H01M 50/213; H01M 50/258; H01M 50/514; H01M 50/264; H02J 2207/20

(57) ABSTRACT

A stackable power storage system is herein described. It comprises a plurality of power modules connectable to each other into a power stack, each one of the power modules comprising at least of a bottom and a top identical to another one of the power modules. The bottom of a top one of the power modules is at least partially nestable in a bottom one of the power modules, The modules comprise connectors connected connectable between power modules when the power modules are stacked thereby at least partially nested relative to each other. Power is transferred between the power modules through the connectors.

### CROSS-REFERENCE TO RELATED APPLICATION

This application claims benefit from U.S. patent application Ser. No. 63/247,403 filed Sep. 23, 2021, the specification of which is hereby incorporated herein by reference in its entirety.

### BACKGROUND

### (a) Field

The subject matter disclosed generally relates to an add-on breaker panel installed between the existing main breaker panel and the electric load of some circuits, and a storage unit power system for providing and managing power to a wide variety of electrical loads. The present subject matter relates more particularly to an add-on breaker panel to isolate, interconnect and monitor some of the circuits of the breaker panel, and a modular and portable storage unit power system having individual battery modules of various capacities that are modular, portable, stackable, electrically chainable, reconfigurable, and rechargeable. The present subject matter relates more particularly to an add-on breaker panel having a bypass connection of the breaker panel that allows independent control of the circuit, and a modular and portable storage unit power system having individual battery modules that are nestable and/or connectable to one another to permit individual modules to be custom connected to one another in a building-block type manner and to be electrically chainable to one another in a plug-and-play type manner. The present subject matter relates furthermore to an add-on circuit panel breaker, and a modular and portable storage unit power system having customizable individual battery modules with pluggable submodules.

### (b) Related Prior Art

Rechargeable storage units for providing power to electrical devices and accessories are generally known. However, many types of rechargeable storage units come in fixed sizes that are not readily reconfigurable for use in a wide variety of applications. Typically, when a relatively high capacity is required, the corresponding storage unit tends to be prohibitively large and heavy and is not conveniently portable to suit the desired mobility of a user. Certain types of portable storage unit are made up of multiple cells, but such cells are usually connected to one another by relatively permanent and inflexible connections, such as bus bars, cable, and clamp connectors, and the like, that do not provide the desired degree of modularity and portability.

### SUMMARY OF THE INVENTION

Accordingly, it would be desirable to provide an improved storage unit power system that overcomes the disadvantages of the known storage unit power systems.

It would be desirable to provide an improved storage unit power system that is (among others) at least some of modular, portable, stackable, electrically chainable, reconfigurable, and rechargeable.

It would also be desirable to provide an improved storage unit system having individual modules that are capable of being transported separately (e.g., carried by different members of a group, etc.) to remote off-grid locations or outposts to provide power to electrical devices, and to be recharged by renewable sources, such as a compact, a solar photovoltaic panel, a wind power generator.

It would also be desirable to provide an improved storage unit power system having individual battery modules of various capacities that can be mixed and matched (or otherwise reconfigured) with one another to suit any of a wide variety of applications or to provide the desired power to a wide variety of loads (i.e., electrical devices, appliances, tools, portable medical devices, etc.).

It would also be desirable to provide an improved storage unit power system having individual battery modules that are stackable or otherwise nestable or connectable with one another (e.g., in a “building block” manner or the like) to create an assembly.

It would also be desirable to provide an improved storage unit power system that has individual battery modules with a mobile or desktop application that readily identifies the real-time remaining charge state of the battery module.

It would also be desirable to provide an improved storage unit power system that is rechargeable from a variety of sources including an electric grid connection (where available), and from a solar photovoltaic panel, a wind power generator, or an EV bi-directional system when an electric grid connection is not available.

It would be desirable to provide an improved storage unit power system that includes any one or more of these advantageous features.

It would be also desirable to provide an improved energy management system allowing to manage different sources of electric power, different resources consuming electric power, and hybrid resources. It is also desirable that the system can face decreases or losses of electric energy from any of the sources, and to manage the electric power extracted from any of the sources at given time by accumulating or compensating with an electric energy buffer and thereby be able to shape the electric energy extracted over time from at least one source of electric energy.

Load centers/breaker panels/breaker boxes are designed to safely distribute the correct amount of electricity to every circuit in the building. However, many of the circuit breakers are thermal-magnetic designed to protect/interrupt the current flow to an electrical circuit with the objective to avoid any damage caused by excess current from an overload or short circuit. Typically, when isolation of a circuit of the breaker panel is required, the corresponding breaker tends to be controlled manually and is not conveniently compatible with the desired internet connectivity. Certain types of breakers can be controlled via Wi-Fi, but such breakers are limited to ON/OFF functions, and the like, which do not provide the desired degree of connectivity between the circuits.

Accordingly, it would be desirable to provide an improved add-on breaker panel that overcomes the disadvantages of the known breaker panel systems.

It would be desirable to provide an improved add-on breaker panel that is (among others) at least some of modular, reconfigurable, and wireless control.

It would also be desirable to provide an improved add-on breaker panel having individual breakers that are capable of isolating, connecting, and monitoring the circuit breakers.

Methods, systems, and devices for managing a smart energy platform are described. The system includes a smart energy storage unit connected to the power outlet of a local circuit in a house (Level I), an Add-on breaker panel that is coupled to the main breaker panel of the local electric grid (Level II), a mobile application to control and monitor the Moduly products, a smart platform that optimizes the energy management of EV charging and solar panel, and temperature control of the smart thermostat and smart water heater (Level III), and a web interface for the utility provider to control and monitor the group of users (Level IV).

In some aspects, the techniques described herein relate to a stackable power storage system including: a first power module including a bottom and a top, wherein the bottom are at least partially nestable on the top of another power module having an identical top when stacked over; a second power module including a bottom identical to the bottom of the first power module, thereby being at least partially nestable over the first power module when stacked over; wherein the tops and bottoms of the first power module, and bottom of the second power module include connectors coupled to each other when the first power module and the second power module are stacked, the connectors being adapted to transmit power and signals between the first power module and the second power module, and wherein at least one of the power modules includes a battery pack adapted to power both power modules.

In some aspects, the techniques described herein relate to a stackable power storage, wherein the top includes a central portion having a periphery and a lip extending over at least part of the periphery of the central portion.

In some aspects, the techniques described herein relate to a stackable power storage, wherein the connectors are about the lips facing toward the central portion of the top.

In some aspects, the techniques described herein relate to a stackable power storage, wherein when the power modules are stacked, the connectors coupling the first power module to the second power module are enclosed.

In some aspects, the techniques described herein relate to a stackable power storage, wherein the first power module includes a lock mechanism locking the power modules together when stacked.

In some aspects, the techniques described herein relate to a stackable power storage, wherein the first power module includes a release mechanism connected to the lock mechanism that, when activated, unlocks the lock mechanism, thereby freeing the power modules from each other.

In some aspects, the techniques described herein relate to a stackable power storage, wherein the first power module includes a casing, and an interface bay at least partially set in the casing, wherein the interface bay is adapted to releasably house a releasable interface module adapted to at least one of power up or deplete power from the battery pack.

In some aspects, the techniques described herein relate to a stackable power storage, wherein the releasable interface module includes spring probe connectors adapted for the first power module to automatically recognize the nature of the mounted releasable interface modules and to adapt characteristics of power transmitted to the releasable interface module.

In some aspects, the techniques described herein relate to a stackable power storage, wherein the first power module includes an AC/DC inverter.

In some aspects, the techniques described herein relate to a stackable power storage, wherein the first power module includes a DC/AC inverter.

In some aspects, the techniques described herein relate to a stackable power storage, wherein the DC\AC inverter is a grid-tie inverter adapted to limit power consumption under a threshold.

In some aspects, the techniques described herein relate to a stackable power storage, further including two DC\AC inverters, wherein one the two DC\AC inverters is a grid-tie inverter.

In some aspects, the techniques described herein relate to a stackable power storage, wherein one of the first power module and the second power module includes a communication interface.

In some aspects, the techniques described herein relate to a stackable power storage, wherein one of the first power module and the second power module includes a power control module and a plurality of switches, wherein the power control module set a mode of operation of the power modules through setting states of the switches.

In some aspects, the techniques described herein relate to a stackable power storage, wherein number of available modes of operations among which is selected the mode of operation is at least 3.

In some aspects, the techniques described herein relate to a stackable power storage, wherein one of the available modes of operation consists in a peak shaving mode of operation during which power received from the grid is limited under a threshold.

In some aspects, the techniques described herein relate to a stackable power storage, both the first power module and the second power module includes a control unit, wherein when stacked, a preset one of the power modules operates as a master power module and the other one of the power modules operates as a slave module.

In some aspects, the techniques described herein relate to a stackable power storage, further including a third power module including a bottom and a top identical to the top and bottom of the first power module, wherein the third power module is stackable with the first power module and the second power module.

In some aspects, the techniques described herein relate to a stackable power storage, wherein the third power module is stackable either at the bottom of the stack or between the first power module and the second power module.

In some aspects, the techniques described herein relate to a stackable power storage, wherein stack of power modules includes a top power module, a bottom power module and an intermediary power module stacked between the top power module and the bottom power module, and wherein the bottom power module is coupled to the top power module through the intermediary power module.

Features and advantages of the subject matter hereof will become more apparent in light of the following detailed description of selected embodiments, as illustrated in the accompanying figures. As will be realized, the subject matter disclosed and claimed is capable of modifications in various respects, all without departing from the scope of the claims. Accordingly, the drawings and the description are to be regarded as illustrative in nature and not as restrictive and the full scope of the subject matter is set forth in the claims.

### BRIEF DESCRIPTION OF THE DRAWINGS

Further features and advantages of the present disclosure will become apparent from the following detailed description, taken in combination with the appended drawings, in which:

FIG. 1 is a schematic depicting electric components of the global functionality and usage of the smart energy storage system of the present disclosure;

FIG. 2 is a schematic of the switches present in the smart energy storage unit;

FIG. 3 is a simplified schematic of the electric circuit comprising the add-on breaker of the smart energy system;

FIG. 4 is a schematic depicting a non-invasive load residential identification;

FIG. 5 is a schematic of the processes associated with the peak load management;

FIG. 6 is a perspective view of a power stack defining a stackable power storage system in accordance with an embodiment;

FIG. 7 is an exploded view of the power stack of FIG. 6 divided into two independent power stacks each comprising many power modules;

FIG. 8 is a perspective view of a series of exemplary interface modules operable with the stackable power storage system of FIG. 6;

FIG. 9 is a view of a power socket of an interface bay with poles specific to particular usages;

FIG. 10 is a perspective view of a power module, and more precisely an A-type control module;

FIG. 11 is an exploded view of a power module, and more precisely the control module;

FIG. 12 is an exploded view of a power module, and more precisely a battery module;

FIG. 13 is a perspective view of one control module and two battery modules when partially nesting one on top of the other to make a power stack;

FIG. 14 is a perspective view of the handle and locking mechanism of the power module, and more precisely the control module;

FIG. 15 is a diagram that schematically depicts components participating in the energy flow of the smart energy platform in accordance with an embodiment;

FIG. 16 is a schematic depicting distributions of various storage energy units in an exemplary house;

FIG. 17 is a diagram depicting functional components managing a smart energy platform in accordance with an embodiment;

FIG. 18 is a representation of a residential utilization of the smart energy storage system in accordance with an embodiment;

FIG. 19 is a floor diagram of a residence with distribution of components of the smart energy storage system in the rooms in accordance with an embodiment;

FIG. 20 is a schematic of components present in the smart energy storage unit in according to an embodiment;

FIG. 21 is a diagram depicting functional components managing a smart energy platform considering remote services and electric circuit components in accordance with an embodiment;

FIG. 22 is a table depicting that through control of a plurality of switches a plurality of different power control modes are available; and

FIG. 23 is a schematic of an add-on breaker panel connected to a main breaker panel and a solar inverter, and in communication with a server in accordance with an embodiment.

It will be noted that throughout the appended drawings, like features are identified by like reference numerals.

### DETAILED DESCRIPTION

The realizations will now be described more fully hereinafter with reference to the accompanying figures, in which realizations are illustrated. The foregoing may, however, be embodied in many different forms and should not be construed as limited to the illustrated realizations set forth herein.

With respect to the present description, references to items in the singular should be understood to include items in the plural, and vice versa, unless explicitly stated otherwise or clear from the text. Grammatical conjunctions are intended to express all disjunctive and conjunctive combinations of conjoined clauses, sentences, words, and the like, unless otherwise stated or clear from the context. Thus, the term “or” should generally be understood to mean “and/or” and so forth.

Recitation of ranges of values and values herein or on the drawings are not intended to be limiting, referring instead individually to all values falling within the range, unless otherwise indicated herein, and each separate value within such a range is incorporated into the specification as if it were individually recited herein. The words “about”, “approximately”, or the like, when accompanying a numerical value, are to be construed as indicating a deviation as would be appreciated by one of ordinary skill in the art to operate satisfactorily for an intended purpose. Ranges of values and/or numeric values are provided herein as examples only and do not constitute a limitation on the scope of the described realizations. The use of all examples, or exemplary language (“e.g.,” “such as”, or the like) provided herein, is intended merely to better illuminate the exemplary realizations, and does not pose a limitation on the scope of the realizations. No language in the specification should be construed as indicating any unclaimed element as essential to the practice of the realizations. The use of the term “substantially” is intended to mean “for the most part” or “essentially” depending on the context. It is to be construed as indicating that some deviation from the word it qualifies is acceptable as would be appreciated by one of ordinary skill in the art to operate satisfactorily for the intended purpose.

In the following description, it is understood that terms such as “first”, “second”, “top”, “bottom”, “above”, “below”, and the like, are words of convenience and are not to be construed as limiting terms.

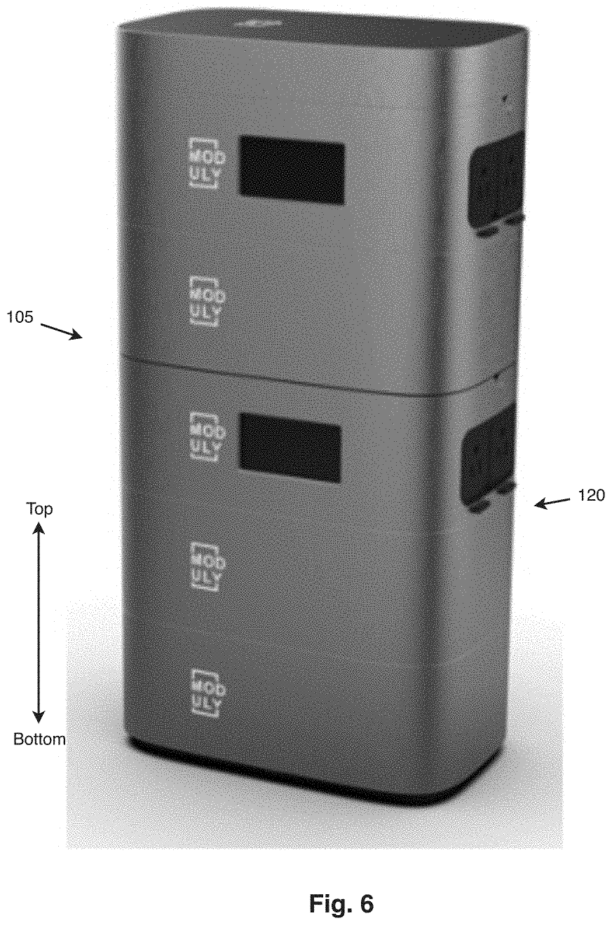

The terms “top”, “up”, “upper”, “bottom”, “lower”, “down”, “vertical”, “horizontal”, “interior” and “exterior” and the like are intended to be construed in their normal meaning in relation with normal installation of the product, with the normal orientation of the components being depicted on FIG. 6.

It should further be noted that for purposes of this disclosure, the term “coupled” means the joining of two members directly or indirectly to one another. Such joining may be stationary in nature or movable in nature and/or such joining may allow for the flow of electricity, electrical signals, or other types of signals or communication between two members. Such joining may be achieved with the two members, or the two members and any additional intermediate members being integrally formed as a single unitary body with one another or with the two members or the two members and any additional intermediate members being attached to one another. Such joining may be permanent in nature or alternatively may be removable or releasable in nature.

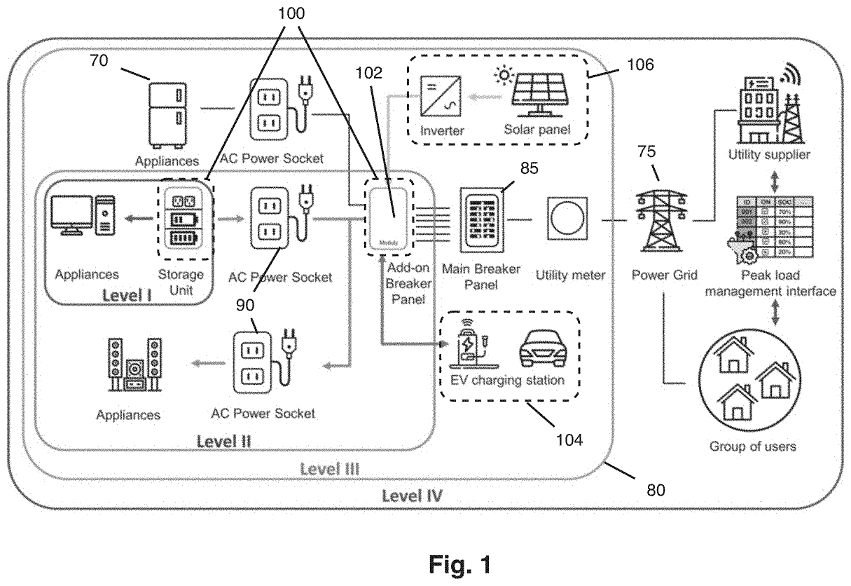

Presented herein is a smart energy platform, as well as methods of its use for withdrawing and supplying electric energy to a local electric grid. The storage unit systems, “plug-and-play”, are easy to integrate within an existing local grid and distribute the energy on it. As illustrated in FIG. 1, the system is divided in four levels and is described in more detail hereinbelow.

Level I—The smart energy storage system provides electric energy to the connected appliances and returns the energy to the local grid. The storage units are modular, portable, stackable, electrically chainable, reconfigurable, and rechargeable.

Level II—The smart adapter system is an add-on breaker panel installed between the existing breaker panel and the electrical load circuit (wired in series) to manage and regulate the energy of a local electric grid. The add-on breaker panel isolates, connects, and monitors some of the circuits of the main breaker panel.

Level III—The mobile application is powered by the Moduly AI smart platform. It controls the water heater operation, optimizes the smart thermostat, smart HVAC, detects an abnormal high consumption of an appliance in the house, gives energy-saving recommendations based on the user's habits, and adjusts the battery level based on the weather forecast.

Level IV—The energy provider web interface collects the user's information through a customizable platform. Utilities will shift to a flexible, adaptive, and individual data-driven power grid. Utilities' platform will allow the energy provider to perform load shaping, voltage support, congestion relief, and transport and distribution (T&D) deferral.

Referring to the drawings, and particularly to FIG. 1, the system 100 is a smart energy platform that comprises a smart energy storage unit 105 (see e.g., FIG. 6) that is connected to the power socket 90 of a local circuit of the house 80 equipped therewith. The system 100 comprises an add-on breaker panel 102 coupled, e.g., hardwired, to the main electric panel 85 which relays power from the energy grid 75 to the house 80, and a software platform that integrates and control the energy storage components and processes, the add-on breaker panel systems, and the other components such as smart appliances 70.

The smart energy storage unit 105 of the system 100 comprises, as is described in more details later, a DC/DC converter used to charge the storage unit, one or more inverters to withdraw electric energy from the storage to power, e.g., directly connected appliances and/or appliances connected to an electric circuit under control of the add-on breaker panel 102.

The function of the add-on breaker panel, 102 is to manage and regulate the energy provided by the electric grid. Potential energy sources comprise a vehicle charging station 104, and a solar panel assembly 106 comprising a solar inverter connected to solar panels.

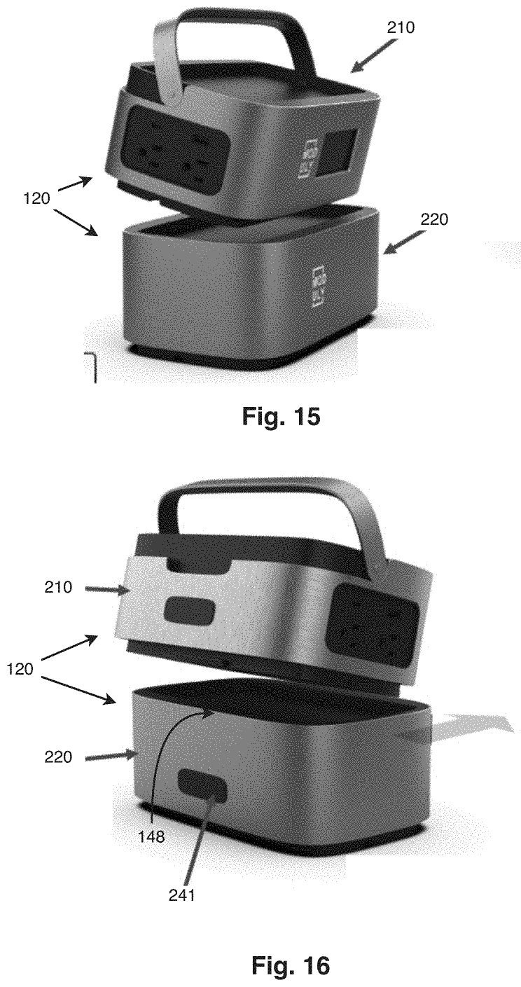

As described later, the smart energy storage unit system 100, alone and/or in combination, comprises two units: a power control module 210 and a power storage module 220 (see e.g., FIG. 15). The control module of the storage unit is 220 adapted to be connected to a wall outlet thereby securing integration of the storage unit 105 to the existing electric circuit, making it easy to scale, flexible and safe to charge and discharge.

The battery charger features four stages: a bulk stage, an absorption stage, a pre-float stage, and a float stage. It comprises a secondary power supply system, such as a supercapacitor, to absorb power peaks. It includes communication means, to manage peer-to-peer communication through a standard communication protocol such as I2C and performed through e.g., Bluetooth™, BLE, Wi-Fi, Lora.

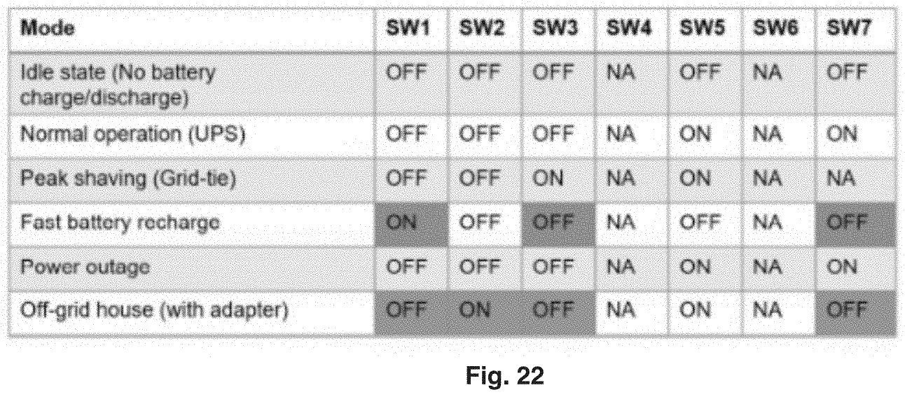

Referring to FIG. 22, a finite-state machine model is implemented to define the different operational modes and their corresponded switch states. The next two modes are electrically constrained that only can happened if the followed condition are meet. A The fast battery recharge mode can only happen if the SW1 is in ON state, SW3 and SW7 are in OFF state. Off-grid house mode can be use only if the SW1, SW3 and SW7 are in OFF state and SW2 in ON state.

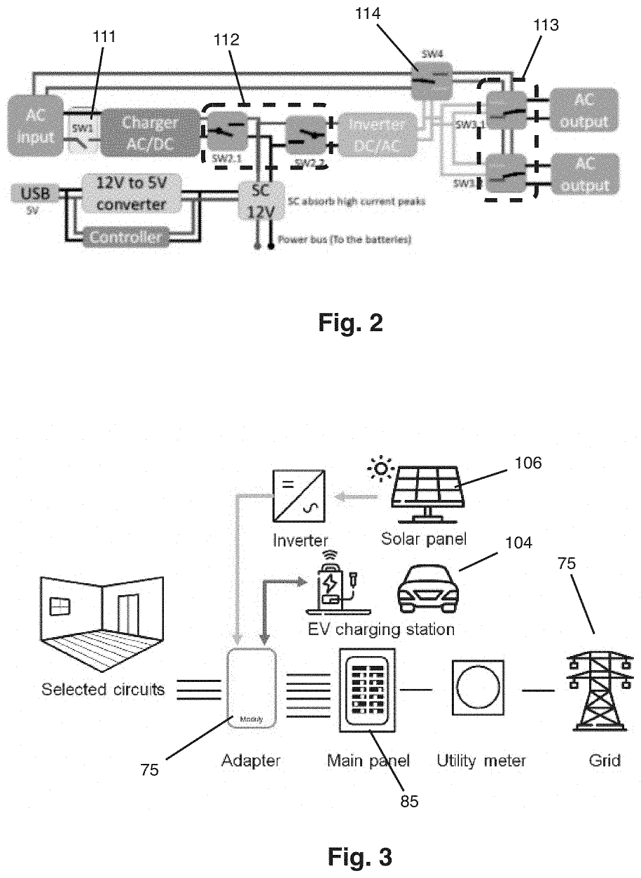

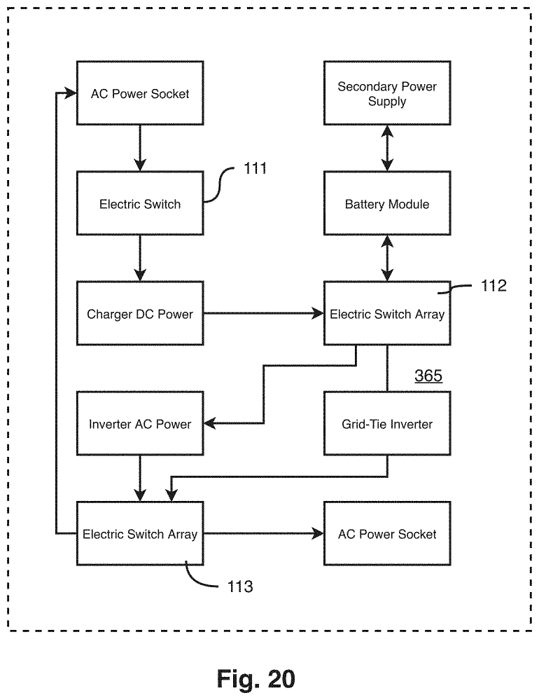

Referring to FIGS. 2 and 20, according to embodiments, the smart energy storage unit comprises an array of electrical switches that connect and disconnect the power outlets based on requirements (see e.g., FIG. 22 for modes of operations comprising up to 6 power-up and off-grid modes and associated switch statuses). An additional function of the array of electrical switches is to allow the flow of electricity between the storage power bus and the grid-tie inverter, off-grid inverter (aka inverter AC power), or the DC/DC converter. Accordingly, switch 111 is designed to activate recharging of the storage unit through the DC/DC converter. The electric switch array 112 is a power bus switch routing the power to the DC/DC converter or to the inverter. The electric switch array 113 is an AC power switch located between the inverters and the grid, wherein each AC outlet has an individual control. The electric switch array 113 is also used to return AC energy to the grid via the main power cord and the control unit. In one embodiment, a switch 114 is also present.

Referring to FIG. 3, the schematic depicts only selected circuits of the house, in other words the electric circuits coupled to the add-on breaker panel 102 controlling and relaying power between the energy grid 75 and appliances (not depicted). It shows that the add-on breaker panel 102 relays power from the main electric panel 85 to the selected circuits, thereby controlling power (none or all) and direction of the power relayed thereby. It further depicts the potential plurality of power sources (e.g., energy grid 75, solar panel assembly 106, and charging station 104) and potential connection being both potential energy sources and energy consumers (e.g., charging station 104).

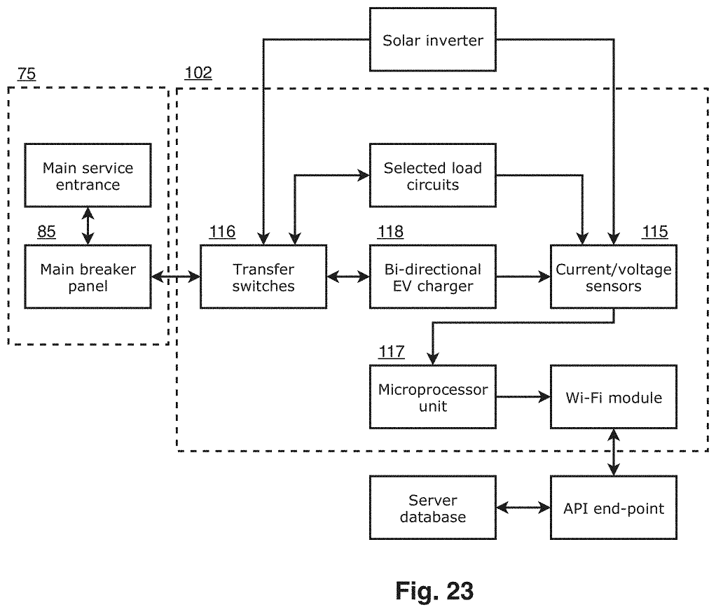

Referring to FIG. 23, the add-on breaker panel 102 is practically installed between the existing breaker panel 85 and the electric load circuit (not depicted on FIG. 23). It comprises:
current/voltage sensors 115 connected circuit;
transfer switch 116 to connect the circuits to the common bus bar, isolating each circuit or connecting it directly to the main panel, and thus to the electric grid;
microprocessor unit 117 that collects and filters the sensor values, shares the collected data with a server database, and locally controls the states of the switches;
component(s) for monitoring the energy production from, e.g., the solar panel and distribution of energy in the circuits where a storage unit is placed;
component(s) for monitoring and regulating the charging process of e.g., the electric vehicle circuit. The control is performed via an API, which receives commands from a platform server featuring algorithm to apply AI to the system; and
a bidirectional EV charger 118 that allows the system to extract energy from e.g., the electric storage of e.g., the electrical vehicle when needed, and operating as an extra energy source when appropriate.

Referring now to other drawings, and more particularly to FIGS. 6, a smart energy storage unit 105 is depicted according to a first exemplary embodiment. The depicted smart energy storage unit 105 includes a plurality of individual power storage modules 120. The individual power storage modules 120 may be provided in a variety of capacities so that a suitable number of power storage modules 120 can be selected and combined to provide the desired power pack to suit an intended application and load device. According to the type of power module, a power control module 210 comprises one or more batteries of an appropriate technology adapted to be able to connect and thereby be considered for the present purpose as a storage unit. However, according to alternative embodiments, a wide variety of capacities may be provided.

The system 100 uses an AI training strategy to optimize energy consumption prediction used to manage the components of the system 100.

According to a realization, the process used for training the data model, aka AI training, comprises the use of four algorithms (a random forest algorithm, a k-nearest neighbor algorithm, a naïve Bayes algorithm, and a linear regression protocol, of initially equal weight). The process obtains thereby an average prediction score according to the current model that is multiplied by the weight of each of the algorithm. This method thereby uses only supervised variables and gives the advantages to each of the algorithms.

The process comprises to remove a less precise algorithm when the process falls under a precision threshold and to re-integrate the removed algorithm after a preset time to help the AI in avoiding “blind spots”, or in other words some undesired sensitivity to particular conditions.

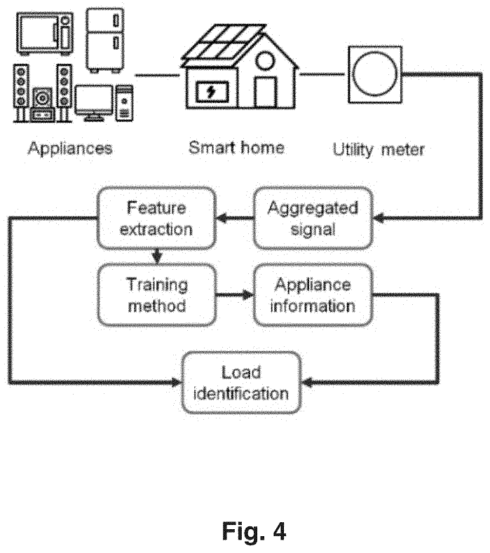

Referring to FIG. 4, the schematic depicts a non-invasive load residential identification. The appliance load monitoring and diagnosis system has an on-line load model learning mechanism, and an off-line pattern recognition training. Using the depicted information, the diagnosis system:
provides valuable energy feedback of individual appliances;
provides effective load diagnosis services of excessive building energy consumption, and helps with component-level faulty operation detection; and
provides high-level demand-response and flexibility demand-side management of the utilities interface.

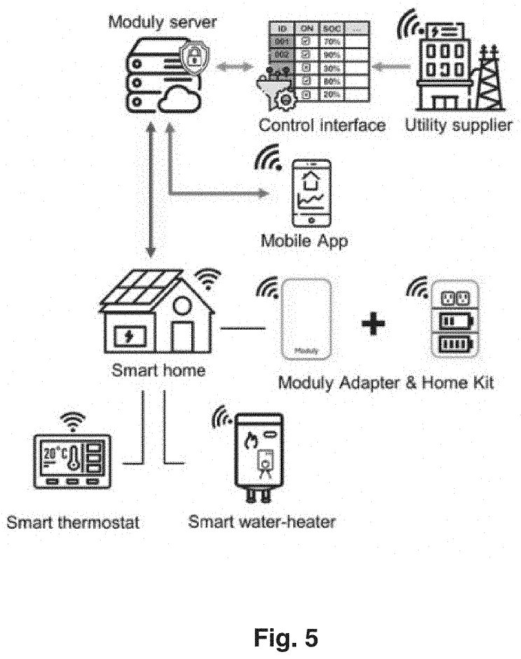

Referring to FIG. 5, the system 100 comprises a peak load management interface. Therethrough, energy providers can control collective features of the users through a customizable platform. Accordingly, utilities can shift to a flexible, adaptative and individual data-driven power grid. The system 100 allows energy providers to perform load shaping, voltage support, congestion relief and transport and distribution (T&D) deferral. Globally, it allows energy suppliers to scale less energy generation and distribution systems solely on peak consumption.

Referring to FIG. 5, the system 100 also includes a mobile application that allows the user to setup a smart environment in which the storage unit, the add-on breaker panel, EV charger, a smart thermostat and water heater can be integrated via Wi-Fi into that environment.

The mobile application allows the user to setup the behaviors preference for each of the smart devices connected, monitor their energy activity and automate their control following a customizable energy management strategy.

The temperature control of the smart thermostat and smart water heater its reflected as a power shifting from the utility supplier perspective, that can be represented as a demand response action.

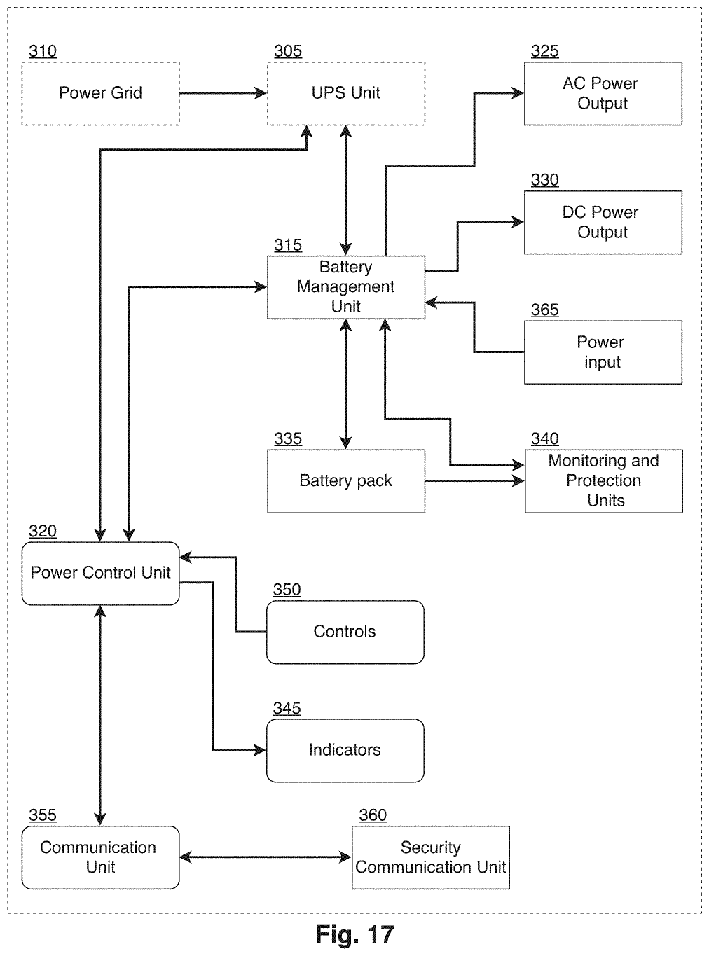

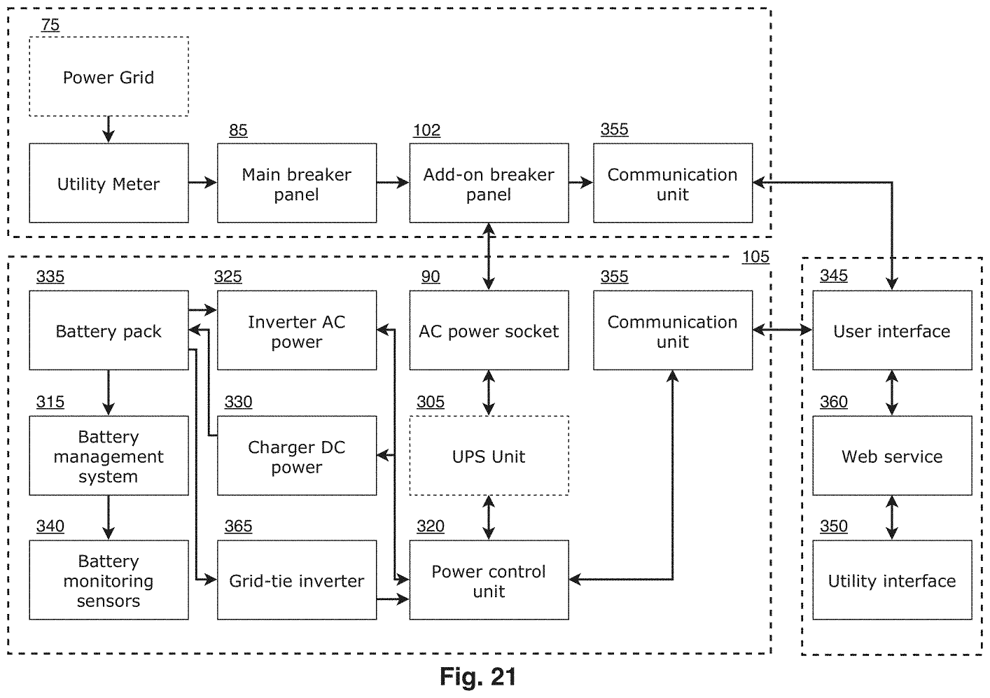

The smart energy storage unit 105 of the system 100 is provided with electronic components (see FIGS. 17 and 21) including (part of battery management unit 315) an input protection circuit, an output protection circuit, a charge controller, a communication controller, and a temperature controller.

The input protection circuit includes an input port that will shut down when the temperature exceeds a predetermined value (e.g., approximately fifty (50) degrees Celsius, etc.) to protect the battery from being overcharged, from overheating, or to be otherwise damaged.

The output protection circuit is connected to output connection ports (e.g., inverter connection port, DC connectors, etc.) and other suitable electronic components for delivering electrical power from the battery to the outlet ports. The output connection ports are embodiments in part by output interface modules that are interchangeable, aka removable and settable, based on needs.

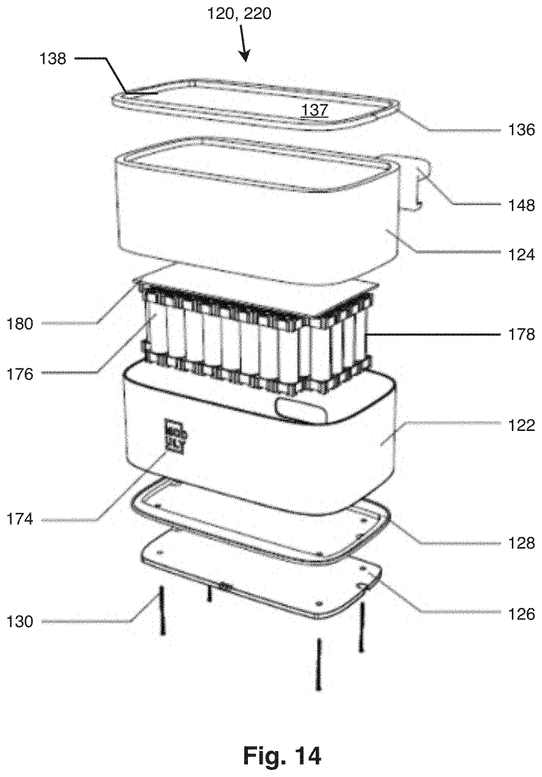

The charge controller circuit regulates the charge to the battery pack 176 (comprising batteries 178 and plate 180, see FIG. 14) and includes protection against an increase of temperature over a limit high temperature.

The communication controller detects the voltage of the battery pack 176, send to the web service the measured values, and controls the display (e.g., LEDs indicators) that indicates the real-time charge of the battery module (e.g., 20%, 40%, 60%, 80%, Full, etc.).

The temperature controller includes a temperature sensor that monitors temperature for example by monitoring the ground and DC input, such that when the temperature sensed by the sensor exceeds a predetermined setpoint (e.g., approximately fifty (50) degrees Celsius), it cuts power off.

According to other embodiments, other control circuits, devices and components may be provided to suit particular applications and functions for the power storage modules 220 of the components of the smart energy storage units 105.

According to the illustrated realization, the modular nature of the individual power storage modules 220 provides the opportunity to assemble modules into a smart energy storage unit 105 comprising individual power storage modules 220 at least partially nested in a plurality of configurations to customize to a desired load. The smart energy storage unit 105 may at any time be disassembled and reassembled into a different smart energy storage unit 105 in a different configuration to power another or a modified load application. The modular nature of the individual power storage modules 220 permits the smart energy storage unit 105 to be separated into individual power storage modules 220 that are each more readily transported, e.g., by a single individual.

For example, when desired for use at locations where transport of an assembled smart energy storage unit 105 is impractical, such as e.g., camping, exploration operations, and search and rescue missions, providing power to electrical devices in remote areas where power is unavailable (e.g., temporarily lost—such as following storms or other natural disasters; or non-existent—such as in certain underdeveloped regions in the world, etc.), the disassembled power storage modules 220 may each be carried or otherwise transported by separate members of a group to the location, where the power storage modules 220 of the smart energy storage unit 105 may then be quickly and conveniently assembled into a particular stack of power storage modules 220 resulting in the desired smart energy storage unit 105 that is suited for the intended electrical loading conditions or devices to be powered.

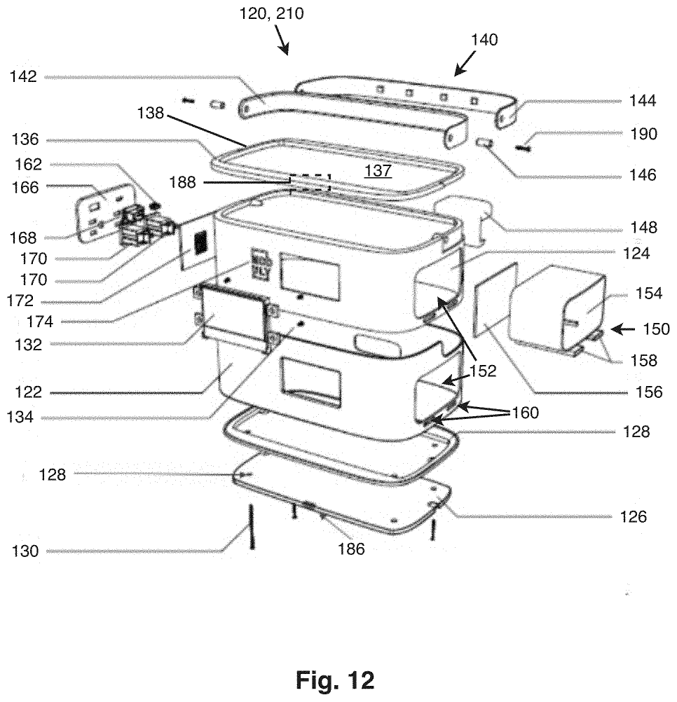

According to realizations, individual storage modules have various weights, with some of them being lightweight (e.g., A-type control module 205—FIG. 10) while others are more heavy-weighted (e.g., the power storage module 220—FIG. 12). According to other embodiments, the device may be any suitable device intended for use in locations without ready access to a grid-based source of electricity. For example, the device to be powered may be a portable medical device such as e.g., a continuous positive airway pressure breathing machine (C-PAP) that would permit a user with a medical condition (e.g., sleep apnea, etc.) to be able to enjoy outdoor activities or other activities that involve sleeping away from home without access to grid-based electricity. According to other embodiments, the medical device may be any portable device intended to assist with any medical condition that might permit the user to gain mobility by having a readily transportable and remotely rechargeable storage unit power supply system.

Referring now to particularly FIG. 6, the smart energy storage unit 105 comprises power storage modules 220 that can be disassembled to facilitate transport.

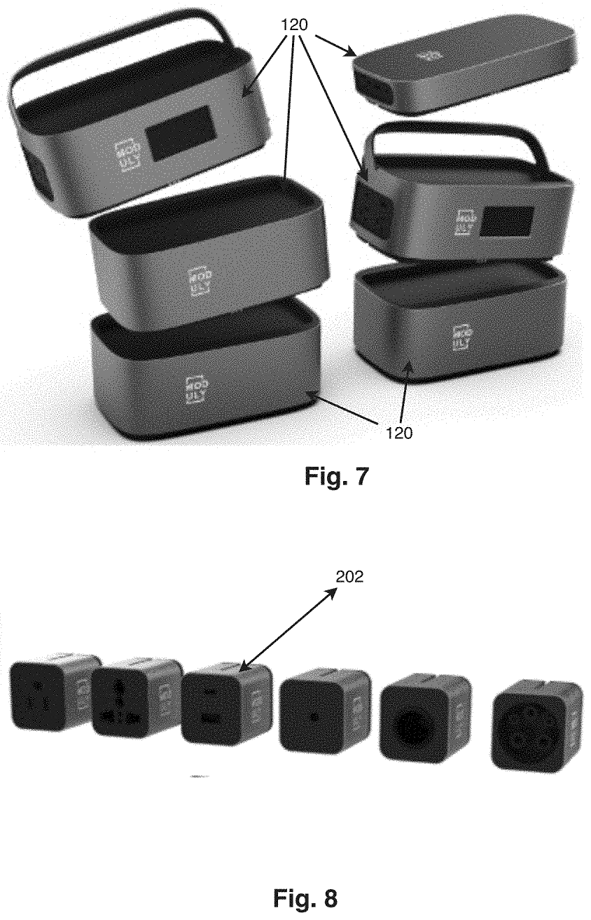

Referring to FIG. 7, more precisely power control module 210, has generally rectangular faces, has a constant footing dimension over the variety of power storage modules 220, aka a width and a depth, and a height varying with the nature of the power storage module 220.

Referring to FIGS. 12, the power control module 210 comprises a frame 122, and according to a preferred realization an aluminum frame. The power control module 210 comprises a bottom plate 126 mounted to the frame 122 through holes 128 and screws 130. The power control module 210 comprises a display 132 (see. e.g., FIG. 11 comprising various power-related LEDs indicators 192, 194, 196, 198, 200) mounted using mounting screws 134. The power control module 210 further comprises a top plate 136 having a central portion 137 and a periphery, and surrounding lips 138 along at least part of the periphery of the central portion 137, mounted to the top of the frame 122. The power control module 210 comprises a handle 140 made, according to a preferred realization, of e.g., plastic.

The handle 140, 142 (comprising mounting holes 144 for mounting components 146, 190) provides minimum disturbance over the general appearance of the power control module 210.

The power control module 210 comprises an interface bay 150 mounted in the opening 152, featuring an interface 156, and defining a room 154, is adapted to receive interface modules 202 (see FIG. 8). The interface bay 150 is mounted to a side opening 152 present in the frame 122. A release button interface 158 part of a release mechanism (extending through openings 160) is also provided about the frame 122 to release the interface modules 202.

Still referring to FIG. 12, the power storage module 220 comprises a lock mechanism 148 mounted to the top of the exterior surface of the housing 124, also referred to as a casing.

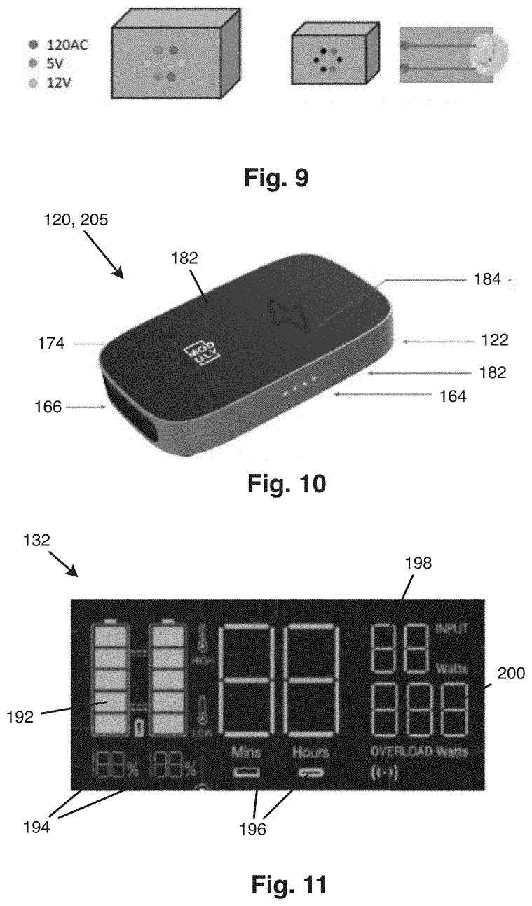

Referring additionally to FIG. 9, the interface bay 150 may use hardwire configuration to detect and adapted to different energy sources and energy consumption types. FIG. 9 depicts use of poles that are specific to e.g., 120/220 VAC usage, 5 VDC usage and 12 VDC usage.

The power control module 210 further comprises an Amphenol USB 3.0 PD type C mounted to the frame 122. The power control module 210 also comprises an Amphenol USB 3.0 QC type A, and two AC Volts power sockets also mounted to the frame 122. These components are mounted to the main control board 172.

Typically, the power control module 210 comprises a logo 174 either embossed, engraved, or printed on a label stuck (preferably) over the front of the housing 124.

Still referring now to FIG. 12, more precisely a power storage module 220, comprises the same base components (housing 124, bottom plate 126, top plate 136, etc.). The power control module 210 further comprises a battery pack 176 comprising a series of single cell batteries connected to provide the desired power.

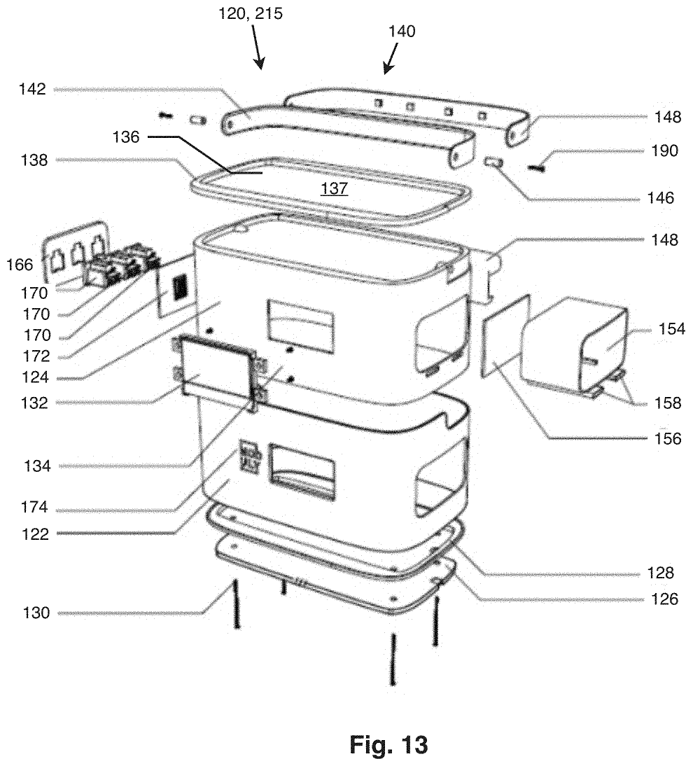

It is to be noted that the power storage modules 215, 220 of FIGS. 13 and 14 are examples of stackable battery modules wherein each one of the power storage modules 215, 220 may be mounted over and partially nested in the other one of the power storage modules 220 into two potential smart energy storage units 105. The coupling of the bedding area is provided by the lock mechanism 148 of the top plate 136 of the power storage module 220 and the bottom plate 126 of either the power control module 210 or the power storage module 220. The foregoing assembly can be installed on an optional base plate.

Referring now particularly to FIG. 10, the A-type control module 205 comprises a retractable 120V connector on the bottom plate (not shown per se but similar to bottom plate 126 of FIG. 11) to ease the transport and the plug-and-play connection to an outlet wall. The A-type control module 205 features a flat top 182 on which is displayed the logo 174 and a wireless charger icon 184 indicative of the location to lay down a wirelessly chargeable device to be charged. The A-type control module 205 features on its front a series of LED indicators 164 providing information on operating status(es) of the A-type control module 205. The A-type control module 205 features on at least one of its sides a feature plate 166 featuring connectors 162 and other features 168, 170 (e.g., one or more USB ports).

The power storage modules 220 are connectable to each other through the top connectors 186 located on the side of the top plate 136 of the exemplary power storage module 220 of FIG. 12 and the bottom connectors 186 of the bottom plate 126 of the exemplary power control modules 210 of FIG. 11. Schematically depicted are bottom connectors 186 located on the side of the bottom plate 126, wherein the bottom connectors 186 and the top connectors 188 are adapted to connect each other when a power control module 210 is partially nested on top of a power storage module 220 and thereby being enclosed by the nesting.

According to a typical realization, an A-type control module 205 (FIG. 10) comprises a storage unit (not depicted) able to provide a power of about one hundred (100) Watt-hour (Wh) or more, a non-removable wireless charger and two non-removable USB type C ports. The A-type control module 205 is typically rechargeable using any of the USB type C ports with a maximum power of 12 Volts at 3 Amperes.

According to a typical realization, a power control module 210 (e.g., FIG. 12) comprises an interface bay 150 able to receive two removable interface modules 202 on one side and non-removable connectors on the opposite side. The power control module 210 comprises protection against voltage overload, overload protection, and internal temperature monitoring and protection. The power control module 210 further comprises protections against short circuit, low temperature, low voltage, overcurrent, and surge. Finally, the power control module 210 can communicate wirelessly through e.g., Bluetooth™, BLE, Wi-Fi, Lora communication protocols, for monitoring purposes.

Typically, the power control module 210 is adapted to be mounted to power storage module 220 into a smart energy storage unit 105. The power control module 210 is adapted, when in a common smart energy storage unit 105, to communicate with power storage module 220 (see FIGS. 12 and 13), when present, operating as the master controller.

It is to be noted that the bottom connectors 186 are designed to be insulated from a surface over which the power module may be laid. The bottom connectors 186 are designed so that no electrical contact can occur with the surface when the smart energy storage unit 105 is placed over a flat surface. A pedestal cover (not shown) can be installed on the bottom of the bottom power storage module 220 to support and to electrically insulate the smart energy storage unit 105.

According to a realization (not depicted), at least one of the bottom connectors 186 and the top connectors 188 feature either a removable cap or a displaceable cap that can be either removed when needed or automatically displaced when partially nesting one power storage module 220 over another. The cap is an exemplary means to protect and prevent contact with the connectors when not in use.

According to an embodiment, the connectors 186, 188 are adapted when coupled to both transmit power between the modules, and to operate as a communication interface, thus to exchange operation signals between the modules.

Referring now to FIG. 12, a LED light (not shown) is present around the power storage module 220, between the bottom plate 126 and the top plate 136 of the power storage module 220.

Referring to FIG. 8, examples of mountable and releasable interface modules 202 are depicted, wherein each of these interface modules 202 can be mounted to a power control module 210 (e.g., power control modules 210 depicted on FIGS. 12 and 13), be dismounted from the power module and replaced with another interface module 202, wherein spring probe connectors are used to connect interface. The spring probe connectors are used such that the system is adapted to automatically recognize the nature of the mountable and releasable interface modules 202 and to adapt the power transmitted to the mountable and releasable interface modules 202 accordingly.

An exemplary list of interface modules comprises, while not limited to, an AC 110 Volts module, an AC 110 Volts/220 Volts module, a USB 3.0 module, a 12V socket module, an electric car module comprising an SAE J1772 connector, and a 5-24 v power jack connector.

Referring to FIGS. 13, 15 and 16, a power control module 210 and a power storage module 220 and/or two power storage modules 220 are stackable (e.g., FIG. 15) by placing the top one (e.g., power control module 210) partially nested over the top of the power storage module 220 and setting them together. Pressure switches 241 activate the lock mechanism 148 of the top plate 136 to the bottom plate 126. To release one from each other, one operator may insert fingers into the pressure switches 241 (part of a release mechanism). You can also unlock the power control module 210 from the power storage module 220 by pressing a touch sensor of the handle 140.

Referring to FIGS. 17 and 21, the shown diagrams depict functional components managing a smart energy platform, including the smart energy storage unit 105 and add-on breaker panel 102 connected to the power grid 310, in accordance with aspects of the present disclosure. The diagram shown in FIG. 21 optionally includes a UPS system 305 connected to the AC power socket 90.

It is to be noted that for the present description the singular is used even though some components may be present in multiple instances in the smart energy storage unit 105, since, when combined, they operate in the same fashion towards a common objective.

In realizations, the smart energy storage unit 105 comprises a battery pack 335 composed of single-cell storage units located in a single power storage module 220 or distributed over a plurality of power storage modules 220.

The battery pack 335 is controlled by the battery management unit 315 distributing power available in the battery pack to the different power outputs (Off-grid Inverter AC power output 325, Grid-tie inverter 365 and Charger DC power output 330). The battery management unit further monitors and controls power exchange with the AC power socket 90 when the smart energy storage unit 105 is charging.

Battery monitoring sensors 340 oversee monitoring, through e.g., sensors, the distribution, aka outputs and inputs of power, to ensure that all operations are performed within safe limits.

A power control unit 320 is connected to the battery management unit 315. The power control unit 320 is responsible for user interfaces, comprising the communication unit 355 used by users to input information and/or commands with the user interface 345 in the smart energy storage unit 105, the user interface 345 responsible to provide information to the user on the status and operation conditions of the system 100, and a communication unit 355 responsible for communication of the system 100 with external agents, such as a Wi-Fi router, web sites, apps, etc. The communication unit 355 operated in cooperation with a secure communication protocol responsible to ensure that all communications exchanged are safe, that the system 100 operates in accordance with commands from the appropriate users.

For example, the communication unit 355 may be an example of a component adapted to transmit the power usage data to a web service 360 or data to the system 100; and receive an energy usage configuration based at least in part on transmitting the power usage data.

In preferred realizations, the communication unit 355 comprises a transceiver (not depicted) adapted to communicate bi-directionally, via antennas, wired, or wireless connections as described above. For example, the transceiver may represent a wireless transceiver and may communicate bi-directionally with another wireless transceiver. The transceiver may also include or be connected to a modem to modulate packets and provide the modulated packets for transmission and demodulate received packets. In some examples, the transceiver may be tuned to operate at specified frequencies. For example, a modem can configure the transceiver to operate at a specified frequency and power level based on the communication protocol used by the modem.

The system 100, wherein the connected devices may consist of power-consuming devices (e.g., a computer, an appliance, a tool, a router, etc.), in power-feeding devices (e.g., a grid-connected AC power socket, a solar cell system, an electric vehicle) and hybrid devices (e.g., an electric bike design to being charged and to charge in a need-based manner or in a cyclic manner).

When the system 100 is present, the smart energy storage unit 105 and the add-on breaker panel 102 can be monitored through Wi-Fi communication, and more particularly through either a user interface 345 or the utility interface 350 as examples.

The user interface 345 or the utility interface 350 may include, for example, profile management, information on operating the system 100, power usage, commands to remotely control (e.g., turn off) aspects of all appliances or devices connected, a notification center and more information.

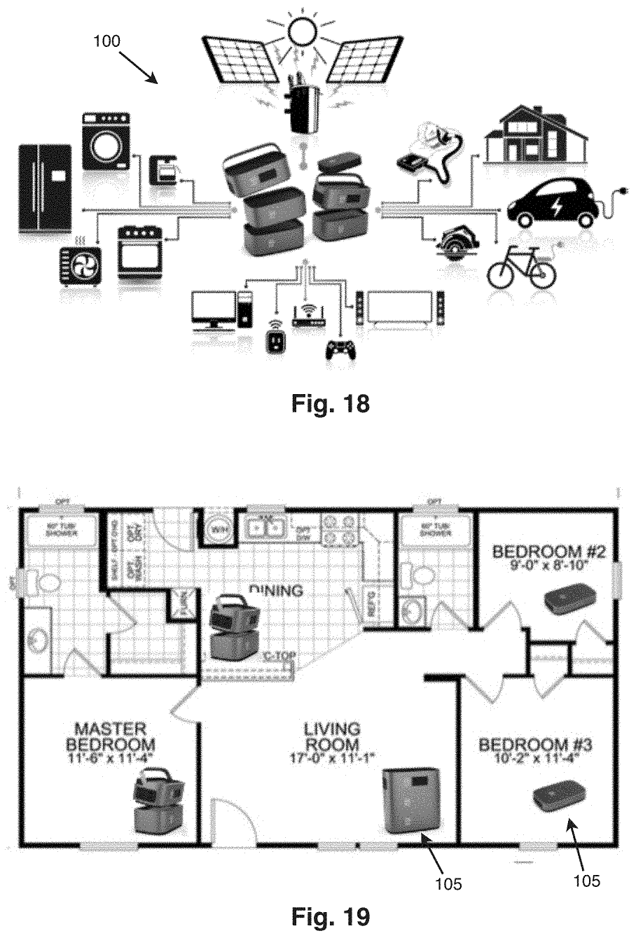

FIGS. 18 and 19 schematically depict an exemplary deployment of one or more smart energy storage unit 105 in a household, wherein, based on the needs. For example, the nominal power of a smart energy storage unit 105 designed to be used in a living room will be according to the number of power storage module 220 stacked. Each room with a smart energy storage unit 105 can have a different power stack.

While preferred embodiments have been described above and illustrated in the accompanying drawings, it will be evident to those skilled in the art that modifications may be made without departing from this disclosure. Such modifications are considered as possible variants comprised in the scope of the disclosure.

1. A stackable power storage system comprising:
a first power module comprising a bottom and a top, wherein the bottom are at least partially nestable on the top of another power module having an identical top when stacked over; and
a second power module comprising a bottom identical to the bottom of the first power module, thereby being at least partially nestable over the first power module when stacked over;
wherein the top and the bottom of the first power module, and bottom of the second power module comprise connectors coupled to each other when the first power module and the second power module are stacked, the connectors being adapted to transmit power and signals between the first power module and the second power module, and
wherein at least one of the power modules comprises a battery pack adapted to power both power modules.

2. The stackable power storage of claim 1, wherein the top comprises a central portion having a periphery and a lip extending over at least part of the periphery of the central portion.

3. The stackable power storage of claim 2, wherein the connectors are about the lips facing toward the central portion of the top.

4. The stackable power storage of claim 3, wherein when the power modules are stacked, the connectors coupling the first power module to the second power module are enclosed.

5. The stackable power storage of claim 2, wherein the first power module comprises a lock mechanism locking the power modules together when stacked.

6. The stackable power storage of claim 5, wherein the first power module comprises a release mechanism connected to the lock mechanism that, when activated, unlocks the lock mechanism, thereby freeing the power modules from each other.

7. The stackable power storage of claim 1, wherein the first power module comprises a casing, and an interface bay at least partially set in the casing, wherein the interface bay is adapted to releasably house a releasable interface module adapted to at least one of power up or deplete power from the battery pack.

8. The stackable power storage of claim 7, wherein the releasable interface module comprises spring probe connectors adapted for the first power module to automatically recognize the releasable interface module and to adapt characteristics of power transmitted to the releasable interface module.

9. The stackable power storage of claim 1, wherein the first power module comprises an AC/DC inverter.

10. The stackable power storage of claim 1, wherein the first power module comprises a DC/AC inverter.

11. The stackable power storage of claim 10, wherein the DC/AC inverter is a grid-tie inverter adapted to limit power consumption under a threshold.

12. The stackable power storage of claim 1, further comprising two DC\AC inverters, wherein one the two DC\AC inverters is a grid-tie inverter.

13. The stackable power storage of claim 1, wherein one of the first power module and the second power module comprises a communication interface.

14. The stackable power storage of claim 13, wherein one of the first power module and the second power module comprises a power control module and a plurality of switches, wherein the power control module set a mode of operation of the power modules through setting states of the switches.

15. The stackable power storage of claim 14, wherein number of available modes of operations among which is selected the mode of operation is at least 3.

16. The stackable power storage of claim 15, wherein one of the available modes of operation consists in a peak shaving mode of operation during which power received from the grid is limited under a threshold.

17. The stackable power storage of claim 13, both the first power module and the second power module comprises a control unit, wherein when stacked, one of the power modules operates as a master power module and another one of the power modules operates as a slave module.

18. The stackable power storage of claim 1, further comprising a third power module comprising a bottom and a top identical to the top and bottom of the first power module, wherein the third power module is stackable with the first power module and the second power module.

19. The stackable power storage of claim 18, wherein the third power module is stackable either at the bottom of the stack or between the first power module and the second power module.

20. The stackable power storage of claim 18, wherein stack of power modules comprises a top power module, a bottom power module and an intermediate power module stacked between the top power module and the bottom power module, and wherein the bottom power module is coupled to the top power module through the intermediate power module.
